(19) United States
(12) Patent Application Publication
(10) Pub. No.: US 2012/0119791 A1
(43) Pub. Date: May 17, 2012

(54) DIGITALIZED SENSOR SYSTEM

(75) Inventor: Hsiung HSIAO, HsinChu (TW)

(73) Assignee: Middleland Sensing Technology Inc., HsinChu City (TW)

(21) Appl. No.: 13/013,555

(22) Filed: Jan. 25, 2011

(30) Foreign Application Priority Data
Nov. 17, 2010 (TW) 099222255

(51) Int. Cl. H03K 5/01

(52) U.S. Cl. 327/100

(57) ABSTRACT

A digitalized sensor system includes a portable electronic device, a sensor unit, a transmission unit and a signal converting unit. The portable electronic device has a first connection portion. The sensor unit is configured for measuring and/or monitoring physical and/or chemical parameters of a target object to generate a digital signal. The transmission unit includes a connecting wire and a second connection portion, the connecting wire adapted to be connected with the sensor unit and the second connection portion, the second connection portion adapted to connect to the first connection portion, and the second connection portion and the first connection portion forming a pluggable interface. The signal converting unit is configured on the transmission unit and adapted for converting the digital signal into a second signal, the second signal adapted to be transmitted to the portable electronic device by the transmission unit.

### FIELD OF THE INVENTION

The present invention generally relates to a portable sensor system with real time sensor functions, and, particularly to a digitalized sensor system with a detachable and interchangeable sensor unit(s).

### BACKGROUND OF THE INVENTION

A conventional portable sensor apparatus generally includes a sensor unit, a display unit and a signal processing unit. The sensor unit has a sensor probe and is for measuring and/or monitoring physical and/or chemical parameters of a target object. The signal processing unit installed in sensor unit or in display unit, is configured to process signals obtained from the sensor unit, for analyzing and storing the resulted data. The display unit has a display screen and is for displaying results of the sensing process. During the measuring process, the user can visualize acquired data displayed on screen.

However, a portable sensor apparatus usually has the sensor unit, the processing unit, and the display unit integrally built, i.e., different types of the sensor units are coupled with different types of processing units and display units respectively, which are not interchangeable. The function of a portable sensor apparatus is hence limited by the type of sensor probes, which results in limited applications of a single sensor apparatus attached. When multiple analyses are involved, such as chemical compositions of both liquid samples and gas samples, different portable sensor apparatuses are usually required, which inevitably increases cost and reduces mobility, and hence results in inconvenience for users.

### SUMMARY OF THE INVENTION

Therefore, an object of the present invention is to provide a sensor system, in which the sensor unit can be assembled with the portable electronic device detachably and interchangeably by the transmission unit cooperative with the signal converting unit, and thus the sensor system can be used to measure or detect different physical and/or chemical parameters conveniently.

The present invention provides a digitalized sensor system, which includes a portable electronic device, a sensor unit, a transmission unit and a signal converting unit. The portable electronic device has a first connection portion. The sensor unit is configured for measuring and/or monitoring physical and/or chemical parameters of a target object to generate a digital signal. The transmission unit includes a connecting wire and a second connection portion, the connecting wire adapted to be connected with the sensor unit and the second connection portion, the second connection portion adapted to connect to the first connection portion, and the second connection portion and the first connection portion forming a pluggable interface. The signal converting unit is configured on the transmission unit and adapted for converting the digital signal into a second signal, the second signal adapted to be transmitted to the portable electronic device by the transmission unit.

In the above digitalized sensor system, the sensor unit can be assembled with the portable electronic device detachably and interchangeably by the transmission unit cooperative with the signal converting unit. Therefore, in the sensor system, if some different physical and/or chemical parameters need to be measured, only one portable electronic device, one transmission unit with the signal converting unit and some different sensor units should be carried. As such, cost, volume and weight of the various components that should be carried can be reduced, and thus the sensing system can be used conveniently.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic exploded diagram of a sensor system in accordance with an embodiment of the present invention.

FIG. 2 is a schematic assembly diagram of the sensor system of FIG. 1.

FIG. 3 is a schematic exploded diagram of a sensor system in accordance with another embodiment of the present invention.

FIG. 4 is a schematic exploded diagram of a sensor system in accordance with another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

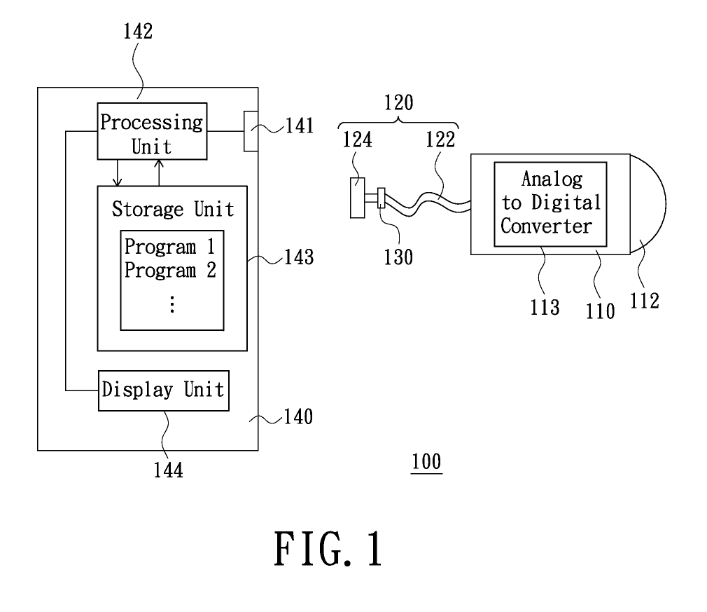

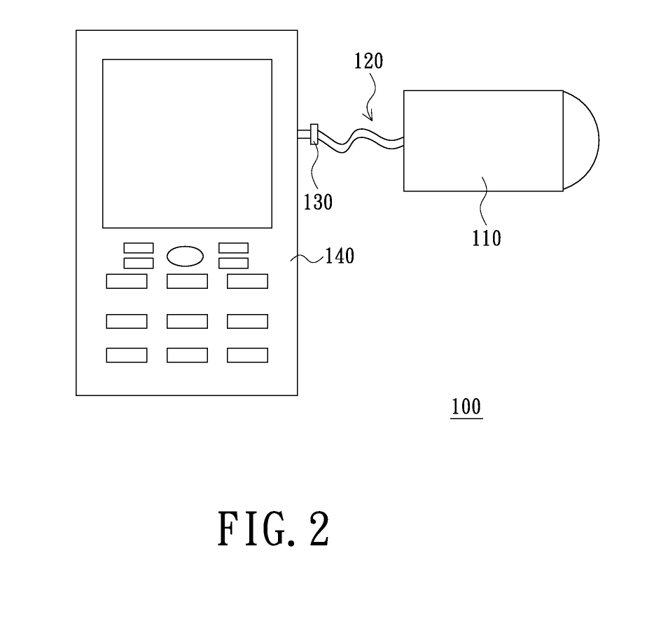

FIG. 1 is a schematic exploded diagram of a sensor system in accordance with an embodiment of the present invention. FIG. 2 is a schematic assembly diagram of the sensor system of FIG. 1. Referring to FIGS. 1 and 2, the sensor system 100 includes sensor unit 110, a transmission unit 120, a signal converting unit 130 and a portable electronic device 140. The sensor unit 110 is used for measuring and/or monitoring physical and/or chemical parameters of a target object (not shown) to generate a digital signal. The signal converting unit 130 is configured on the transmission unit 120. The portable electronic device 140 is used to combine with different sensor units 110 by the transmission unit 120, so as to receive and process the signal obtained by the corresponding sensor unit 110.

The sensor unit 110 can includes a sensor probe 112 and an analog-to-digital (A/D) converter 113. The sensor probe 112 is configured for the measurement and/or monitoring of physical and/or chemical parameters of the target object and generating analog signals corresponding to the parameters. Such analog signals generally are micro-voltage signals or micro-current signals. The analog signals e.g., the micro-voltage or micro-current signals can be converted into digital signals by the A/D converter 113.

The target object can be liquid, gas or solid. Types of the sensor unit 110 and the physical and/or chemical parameters measured by the sensor unit 110 would be various according to the different sensor probes 112. In the embodiment, the sensor unit 110 can be a chemical sensor, an ion sensor, a gas sensor or a biological sensor and the present invention is not limited herein. The biological sensor is, for example, a blood glucose sensor, a blood oxygen sensor or a urea nitrogen sensor. Corresponding to the type of the sensor unit 110, the physical and/or chemical parameters sensed by the sensor probe 112 are, for example, chemical composition, liquid medicine concentration, ion composition, ion concentration, gas composition, gas concentration, gas humidity, gas pressure, blood glucose concentration, blood oxygen saturation or protein concentration of the target object.

The transmission unit 120 is connected with the sensor unit 110 and used to convert the digital signal into a second signal, and then the second signal can be transmitted to the portable electronic device 140 by the transmission unit 120, wherein the sensor unit 110 is detachable and exchangeable to the transmission unit. The transmission unit 120 includes a connecting wire 122 and a second connection portion 124. The signal converting unit 130 can be an integrated circuit, which is configured on the connecting wire 122. Moreover, the sensor unit 110 is powered by the portable electronic device 140 via the transmission unit 120.

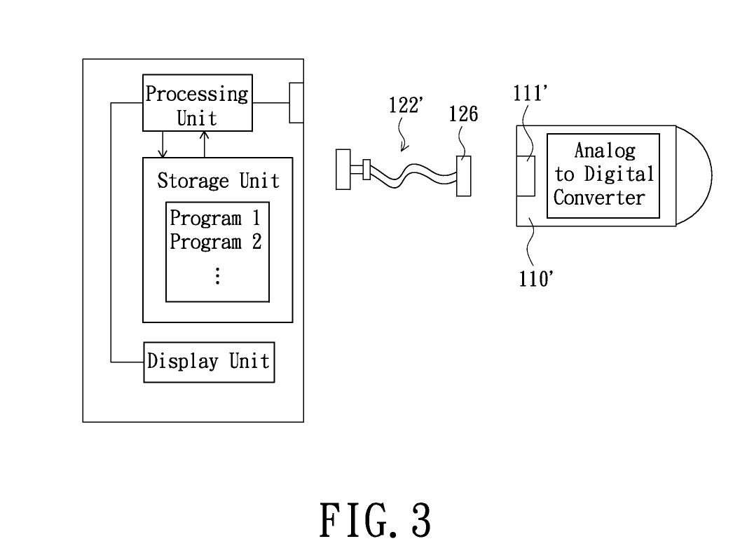

In alternative embodiment, the signal converting unit 130 can be configured on other portion of the transmission unit 120, such as the second connection portion 124. The second connection portion 124 and a first connection portion 141 of the portable electronic device 140 form a pluggable interface. For example, the second connection portion 124 can be a USB plug, and the first connection portion 141 can be a USB port. The signal converting unit 130 is used to convert the digital signal into a second signal. The connecting wire 122 is connected with the sensor unit 110 and the second connection portion 124, respectively. The second connection portion 124 connects to the first connection portion 141, so that the second signal can be transmitted to the portable electronic device 140 by the transmission unit 120. The connecting wire 122 and the sensor unit 110 can be connected with each other by applying universal asynchronous receiver/transmitter (UART), inter-integrated circuit (I²C) or RS-232 standard, and the connecting wire 122 and sensor unit 110 can be directly combined with each other. In an alternative embodiment, referring to FIG. 3, the connecting wire 122′ and the sensor unit 110′ can be connected with each other by a third connection portion 111′ and a fourth connection portion 126. The third connection portion 111′ and the fourth connection portion 126 can form a pluggable interface. The third connection portion 111′ can be disposed on the sensor unit 110′ and can be a port. The fourth connection portion 126 can be disposed on connecting wire 122′ and can be a plug. In addition, the second signal is a signal that conforms to universal serial bus (USB) standard, such as USB 2.0 standard, USB 3.0 standard or USB On-The-Go (USB OTG) standard.

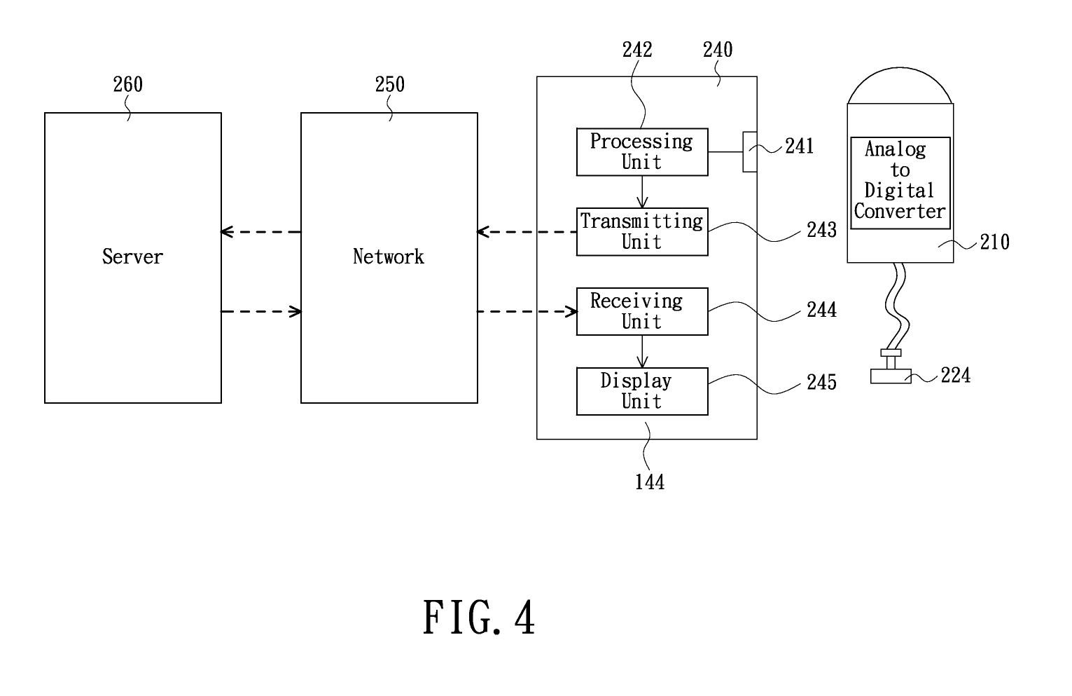

The portable electronic device 140 can be a mobile phone or a notebook computer. In the embodiment, the portable electronic device 140 includes a processing unit 142, a storage unit 143 and a display unit 144. The storage unit 143 can be used for storing one or more programs that are respectively corresponding to different sensor units 110. The processing unit 142 receives the digital signals from the installed sensor unit 110 through the electrical connection between the first connection portion 141 and the second connection portion 124, selects an appropriate program from the storage unit 143 manually or automatically according to the digital signals, analyzes the digital signals by the selected program, acquires parameters of a target object, and controls the display unit 144 to display the analyzing results from the processing unit 142. In an alternative embodiment, referring to FIG. 4, the portable electronic device 240 can includes a processing unit 242, a transmitting unit 243, a receiving unit 244 and a display unit 245. The processing unit 242 receives the digital signals from the installed sensor unit 210 through the electrical connection between the first connection portion 241 and the second connection portion 224, and transmits the digital signals to the transmitting unit 243. The transmitting unit 243 sends the digital signals to a server 260 via a network 250. The server 260 processes the digital signals to obtain a result and then sends the result back to the receiving unit 244. The display unit 245 is electrically connected with the receiving unit 244 to output/display the result.

In the embodiments, the sensor unit 110 can be assembled with the portable electronic device 140 detachably and interchangeably by the transmission unit 120 cooperative with the signal converting unit 130. Therefore, in the sensor system 100, if some different physical and/or chemical parameters need to be measured, only one portable electronic device 140, one transmission unit 120 with the signal converting unit 130 and some different sensor units 110 should be carried. As such, volume and weight of the various components that should be carried can be reduced, and thus the sensing system 100 can be used conveniently.

Furthermore, only one portable electronic device 140, one transmission unit 120 with the signal converting unit 130 and some different sensor units 110 should be carried while some different physical and/or chemical parameters are measured by the sensing system 100, therefore cost for buying different electronic devices can be reduced, and thus the cost of sensing work can be reduced.

As mentioned above, each of the embodiments of the present invention at least has one of the following advantages or other advantages.

First, the sensor unit can be assembled with the portable electronic device detachably and interchangeably by the transmission unit cooperative with the signal converting unit. Therefore, in the sensor system, if some different physical and/or chemical parameters need to be measured, only one portable electronic device, one transmission unit with the signal converting unit and some different sensor units should be carried. As such, volume and weight of the various components that should be carried can be reduced, and thus the sensing system can be used conveniently.

Second, only one portable electronic device, one transmission unit with the signal converting unit and some different sensor units should be carried while some different physical and/or chemical parameters are measured by the sensing system, therefore cost for buying different electronic devices can be reduced, and thus the cost of sensing work can be reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A digitalized sensor system, comprising:
a portable electronic device having a first connection portion;
a sensor unit configured for measuring and/or monitoring physical and/or chemical parameters of a target object to generate a digital signal;
a transmission unit comprising a connecting wire and a second connection portion, the connecting wire adapted to be connected with the sensor unit and the second connection portion respectively, the second connection portion adapted to connect to the first connection portion, and the second connection portion and the first connection portion forming a pluggable interface; and
a signal converting unit configured on the transmission unit and adapted for converting the digital signal into a second signal, the second signal adapted to be transmitted to the portable electronic device by the transmission unit.

2. The digitalized sensor system as claimed in claim 1, wherein the second signal is a signal that conforms to USB standard.

3. The digitalized sensor system as claimed in claim 1, wherein the connecting wire and the sensor unit are connected with each other by applying UART, I²C or RS-232 standard.

4. The digitalized sensor system as claimed in claim 1, wherein the interface of the second connection portion and the first connection portion is a USB interface.

5. The digitalized sensor system as claimed in claim 1, wherein the signal converting unit is an integrated circuit.

6. The digitalized sensor system as claimed in claim 1, wherein the digitalized sensor system further comprises a third connection portion and a fourth connection portion, the third connection portion disposed on the sensor unit, the fourth connection portion disposed on connecting wire and corresponding to the third connection portion, and the third connection portion and the fourth connection portion forming a pluggable interface.

7. The digitalized sensor system as claimed in claim 1, wherein the sensor unit is detachable and exchangeable to the transmission unit.

8. The digitalized sensor system as claimed in claim 1, wherein the transmission unit transmit power from the portable electronic device to the sensor unit.
